(19) United States
(12) Patent Application Publication
(10) Pub. No.: US 2007/0243645 A1
(43) Pub. Date: Oct. 18, 2007

(54) High-Power LED Chip Packaging Structure And Fabrication Method Thereof

(76) Inventors: Cheng Lin, Zhonghe City (TW); Hua-Hsin Su, Ping-Chen City (TW); Masami Nei, Zhonghe City (TW)

Correspondence Address: LIN & ASSOCIATES INTELLECTUAL PROPERTY, P.O. BOX 2339, SARATOGA, CA, 95070-0339, US

(21) Appl. No.: 11/765,541

(22) Filed: Jun. 20, 2007

Related U.S. Application Data
(62) Division of application No. 11/294,135, filed on Dec. 3, 2005.

(51) Int. Cl. H01L 33/00

(52) U.S. Cl. 438/26; 257/E33.057

(57) ABSTRACT

A packaging structure and a related fabrication method for high-power LED chip are provided herein, which mainly contains a base made of a metallic material and an electrically insulating material integrated into a single object. The metallic material forms a heat sinking seat in the middle of the base, which is exposed from the top surface of the base, and from the bottom surface or a side surface of the base. The metallic material also forms a plurality of electrodes surrounding the heat sinking seat, which are exposed from the top surface of the base, and from the bottom surface or a side surface of the base, respectively. The electrically insulating material is interposed between the electrodes and the heat sinking seat so that they are adhere together, and so that the heat sinking seat and any one of the electrodes, and any two electrodes are electrically insulated. The packaging structure achieves superior heat dissipation efficiency by separating the electricity and heat dissipation channels and, in another way, is applicable in mass production for a significantly reduced production cost.

### CROSS-REFERENCES TO RELATED APPLICATIONS

This is a division of U.S. patent application Ser. No. 11/294,135, filed Dec. 3, 2005.

### BACKGROUND OF THE INVENTION

1. Field of the Invention

The present invention generally relates to light emitting diodes, and more particularly to a packaging structure for a high-power light emitting diode chip and a related fabrication method thereof.

2. The Prior Arts

Spirited research activities have been focused on high-power light emitting diodes (LEDs) in the relevant industries in recent years. One of the most important considerations for the package of a high-power LED chip is about the appropriate handling of the high temperature and the heat produced by the high-power LED chip, so that the functionality, performance, and operational life of the LED chip is not compromised.

FIG. 1a is a schematic sectional view showing a conventional packaging structure of a LED chip. As illustrated, the LED chip (or, some people refer to it as a LED die) 16 is positioned on top of a substrate 19 made of Bismaleimide Triazine (BT) resin. The electrodes (not shown) of the LED chip 16 are connected, by bonding wires (or, some people refer to them as gold wires) 13, to the copper foil 15 previously configured on the substrate 19 for establishing electrical connection to external circuitry. The LED chip 16 is surrounded by a reflection mirror 14. A resin 17 is filled to seal and protect the LED chip 16 and the bonding wires 13 inside. This conventional packaging structure is applicable in mass production and, therefore, contributes to a lower production cost. However, in this conventional structure, the heat produced by the LED chip 16 could only be dissipated through the thin copper foil 15 as resin is not an acceptable thermal conductor. In other words, the copper foil 15 functions as a conduction channel for both electricity and heat for the LED chip 16, and, if the LED chip 16 is a high-power one, such an arrangement is not appropriate for handling the high-volume heat produced by the high-power LED chip 16.

U.S. Pat. No. 6,274,924 discloses a packaging structure which offers separate conduction channels for electricity and heat. To facilitate the explanation, the reference diagram of U.S. Pat. No. 6,274,924 is included here as the accompanied drawing FIG 1b. As shown in FIG. 1b, the disclosed packaging structure molds a metallic lead frame 12 in an electrically insulating plastic body that can withstand high temperature. The LED chip 16 is positioned on top of a thermally conductive but electrically insulating submount 18. The LED chip 16 and the submount 18 are then positioned on top of a metallic heat sinking element 10 which is usually made of copper. Also on top of the heat sinking element 10, there could be an optional reflection mirror 14 under the LED chip 16 and the submount 18. The heat sinking element 10, along with the LED chip 16 and the submount 18, is then positioned inside a preserved space of the lead frame 12's plastic body. The electrodes (not shown) of the LED chip 16 are connected to the lead frame 12 also by bonding wires (not shown). At last, the LED chip 16 and the bonding wires is covered and protected by a previously prepared transparent protection lens 20 filled with resin (not shown).

The packaging structure provided by the U.S. Pat. No. 6,274,924 offers satisfactory heat dissipation by separating the conduction channels for electricity and heat. However, the production process as described above is rather complex and a higher production cost is therefore inevitable. In addition, the lead frame 12 and the protection lens 20 have to be prepared in advance by molding, leading to a very inflexible production process, let alone the cost involved for the molds. For example, if the packaging structure depicted in FIG. 1b is to be used to package two or more LED chips 16, the lead frame 12 and the protection lens 20 have to be re-designed and manufactured.

### SUMMARY OF THE INVENTION

Accordingly, the major objective of the present invention is to provide a packaging structure and a related fabrication method for packaging a high-power LED chip which, in one way, achieve superior heat dissipation efficiency and, in another way, are applicable in mass production for a significantly reduced production cost.

The packaging structure provided by the present invention mainly contains a base, a reflection plate, the LED chip being packaged, bonding wires for connecting the electrodes of the LED chip, and a transparent filler or lens for sealing and protecting the LED chip and the bonding wires. The base, having a flat form factor, is made of a metallic material and an electrically insulating material integrated into a single object. The metallic material forms a heat sinking seat in the middle of the base having appropriate distances to the edges of the base. The heat sinking seat is exposed from the top surface of the base, and from the bottom surface or a side surface of the base. The metallic material also forms a plurality of electrodes surrounding the heat sinking seat. The electrodes are exposed from the top surface of the base, and from the bottom surface or a side surface of the base. The electrically insulating material is interposed between the electrodes and the heat sinking seat so that they are adhere together, and so that the heat sinking seat and any one of the electrodes, and any two electrodes are electrically insulated.

The LED chip being packaged is adhered to the exposed top surface of the heat sinking seat. The positive and negative electrodes of the LED chip are connected separately to the exposed top surfaces of the base's electrodes respectively. The reflection plate is fixedly attached to the base via an appropriate means so that a vertical through hole of the reflection plate exposes the LED chip on top of the heat sinking seat of the base. The light emitted from the LED chip, as a result, is able to radiate outward. The reflection plate is made of a metallic material having high reflectivity, or of a non-metallic material in which the wall of the through hole is coated with a film or a layer of high reflectivity material. The filler or the protection lens is made of a transparent material such as resin, and is placed inside the through hole so as to seal and protect the LED chip and the bonding wires.

The base of the packaging structure has a simplified structure and, therefore, is very suitable for mass production. The fabrication method provided by the present invention use a single metallic plate to produce the bases for a large number of units of the packaging structure simultaneously. The heat sinking seats and the electrodes of the bases are formed by etching the metallic plate in a single operation or by etching the two major surfaces of the metallic plate in separate operations. Then, the insulating material is filled between the heat sinking seats and the electrodes. Subsequently, the reflection plate is adhered to the base; the LED chip is fixed to the top of the heat sinking seat; bonding wires are connected between the electrodes of the LED chip and the exposed top surfaces of the base's electrodes; the filler is stuffed inside the through hole of the reflection plate; and, at last, the units of the packing structure are separated by cutting.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1a is a schematic sectional view showing a conventional packaging structure of a LED chip.

FIG. 1b is the reference diagram of U.S. Pat. No. 6,274,924.

FIG. 2a is a schematic sectional view showing the packaging structure according to a first embodiment of the present invention.

FIG. 2b is a blown-up view showing the packaging structure of FIG. 2a.

FIG. 2c is a schematic sectional view showing the packaging structure according to a second embodiment of the present invention.

FIG. 2d is a schematic sectional view showing the packaging structure according to a third embodiment of the present invention.

FIG. 2e is a schematic sectional view showing the packaging structure according to a fourth embodiment of the present invention.

FIG. 2f is a schematic sectional view showing the packaging structure according to a fifth embodiment of the present invention.

FIG. 3a is a perspective view showing the base and the packaging structure for two LED chips according to an embodiment of the present invention.

FIG. 3b is a perspective view showing the base and the packaging structure for three LED chips according to an embodiment of the present invention.

FIGS. 4a˜4g show the results of the processing steps of a fabrication method according to an embodiment of the present invention.

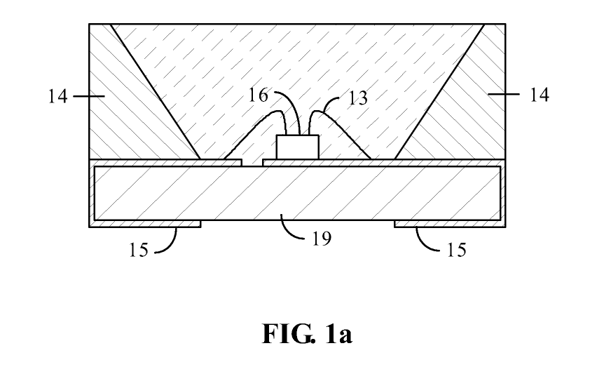

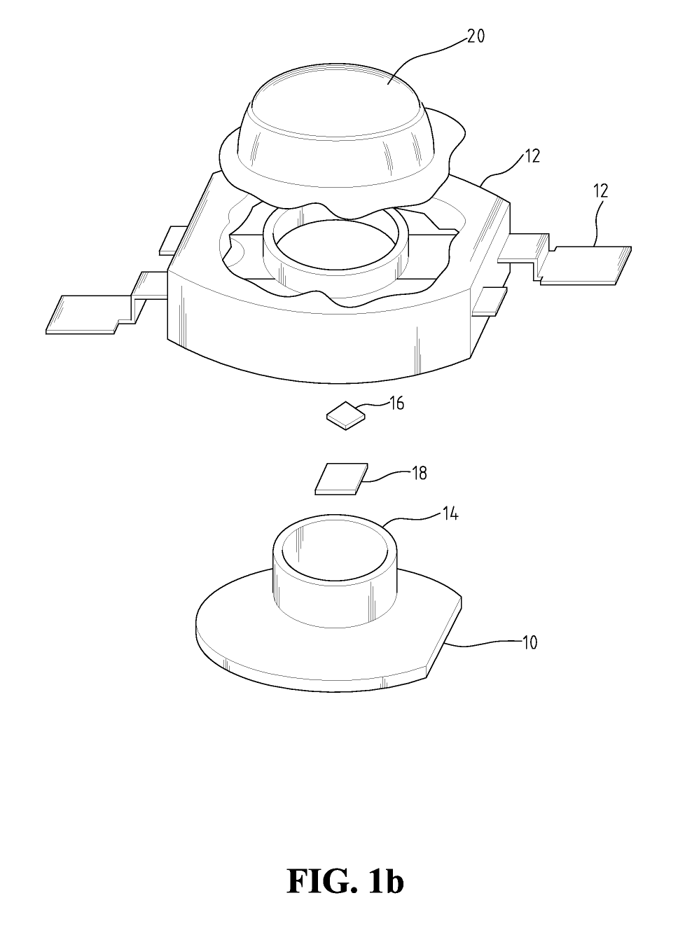

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

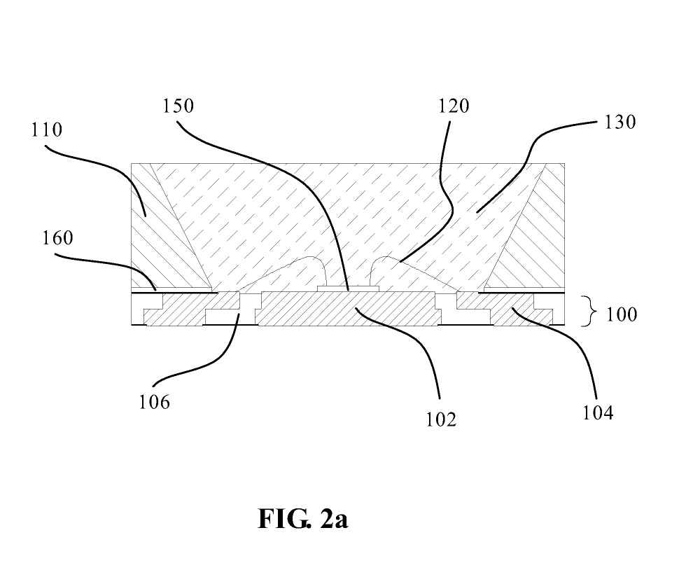

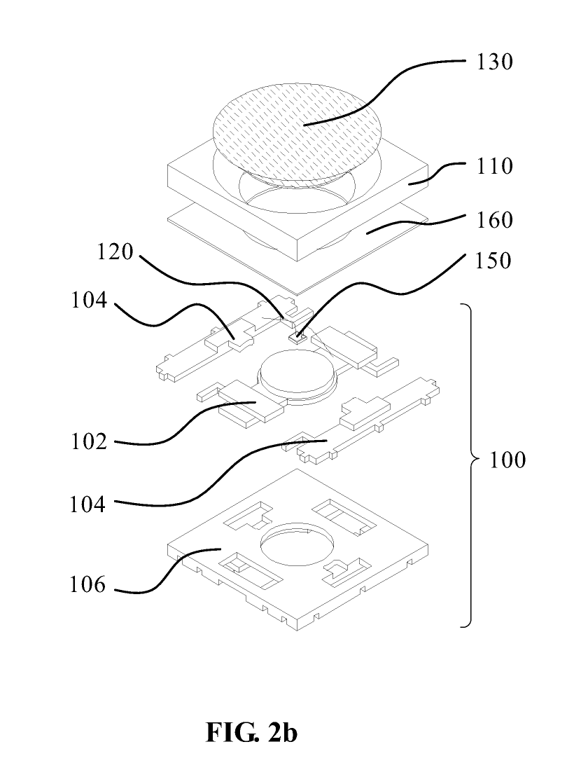

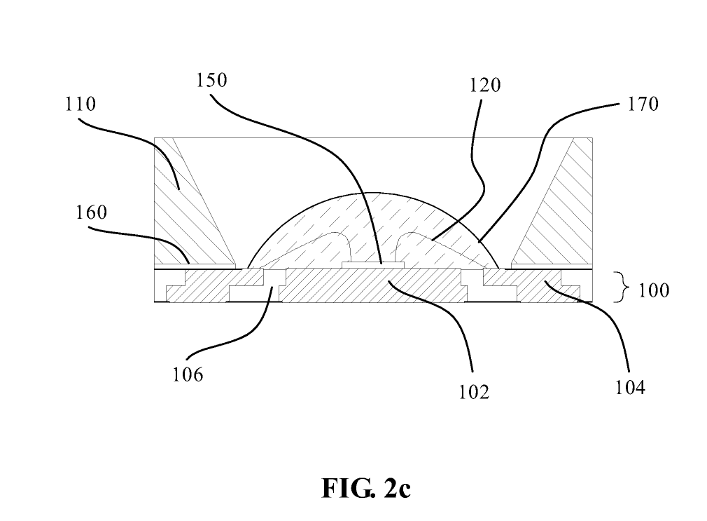

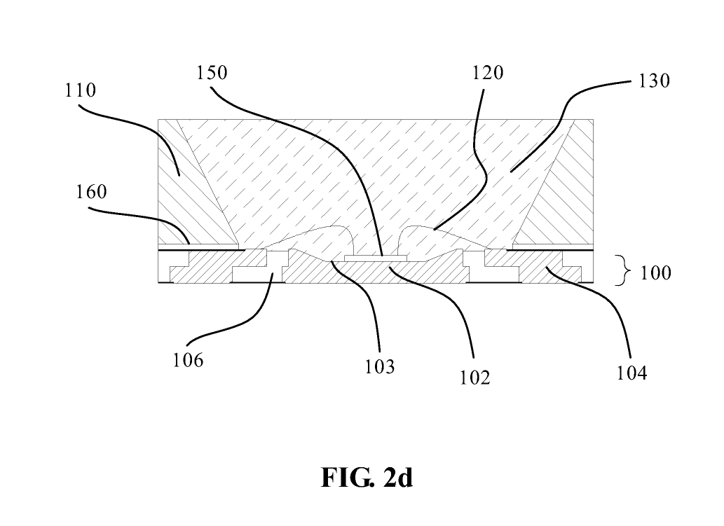

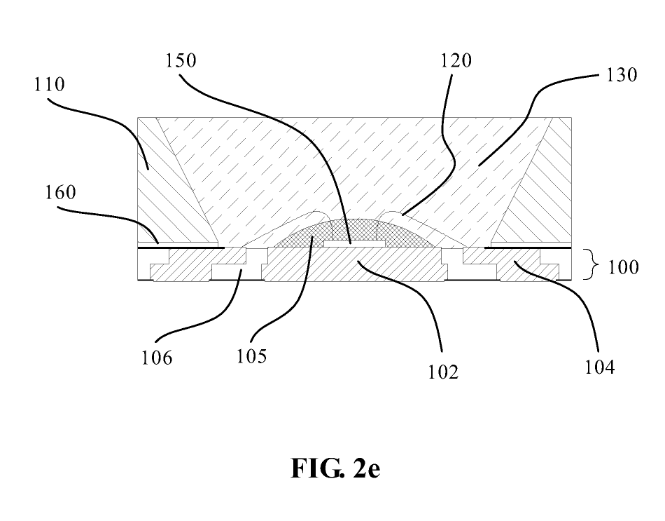

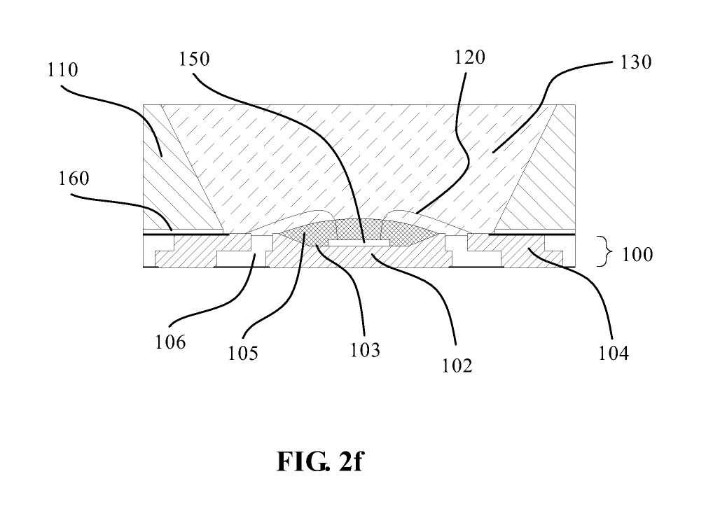

FIGS. 2a and 2b are schematic sectional view and blown-up view of the packaging structure according to a first embodiment of the present invention. As illustrated, the packaging structure provided by the present embodiment contains at least a base 100, a reflection plate 110, the LED chip being packaged 150, a plurality of the bonding wires 120, and a transparent filler 130. The base 100, having a flat form factor, is composed of a heat sinking seat 102, a plurality of electrodes 104, and an insulator 106, integrated together into a single solid object. The heat sinking seat 102 and the electrodes 104 are made of a metallic material having high electrical and thermal conductivities. The insulator 106, on the other hand, is made of an insulating material such as resin or the like.

The heat sinking seat 102 is positioned in the middle of the flat base 100 with appropriate distances to the edges of the base 100. The heat sinking seat 102 is exposed both from the top surface of the base 100, and from at least one of the bottom surface and a side surface of the base 100. In the present embodiment, the heat sinking seat 102 has multiple exposures on the top surface of the base 100 so as to enhance the heat dissipation by increasing its contact area with air. Please note that the shape of the heat sinking seat 102 as shown in FIGS. 2a and 2b is only exemplary; other appropriate shapes could also be adopted by the heat sinking seat 102. The electrodes 104 are positioned at appropriate locations around the heat sinking seat 102. Similarly, the electrodes 104 are exposed both from the top surface of the base 100, and from at least one of the bottom surface and a side surface of the base 100, respectively. Please also note that the shapes of the electrodes 104 as shown in FIGS. 2a and 2b are only exemplary. Generally, for the single-chip packaging of the present embodiment, there are two electrodes 104 for connecting to the positive and negative electrodes of the chip 150 respectively. In alternative embodiments which provide multiple-chip packaging, the number of the electrodes 104 is twice the number of the chips 150. The insulator 106 makes up the rest of the base 100. The insulator 106 therefore is located between the heat sinking seat 102 and the electrodes 104 so as to, for one thing, adhere the heat sinking seat 102 and the electrodes 104 together and, for another thing, form the insulation between the heat sinking seat 102 and any one of the electrodes 104, and between any two electrodes 104. The fabrication of the base 100 will be described in details later.

The reflection plate 110 also has a flat form factor with a vertical through hole (not numbered) at an appropriate location in the middle. The reflection plate 110 is made of a metallic material having high reflectivity (e.g., aluminum), or it could be made of an insulating material such as resin but the wall of the through hole has a white coating, or is coated with a film made of highly reflective material such as silver. The reflection plate 110 is adhered to the base 100 with a layer of an appropriate adhesive 160. When the reflection plate 110 is made of a metallic material, the adhesive 160 also provides the insulation between the reflection plate 110 and the base 110's heat sinking seat 102 and electrodes 104. The location and aperture of the through hole are properly configured so that, after the reflection plate 110 is joined with the base 100, the top surface of the heat sinking seat 102 and at least some portion of the top surface of the electrodes 104 are exposed for the fixation of the LED chip 150 and the connection of the bonding wires 120 respectively. As such, when the LED chip 150 is fixed on the exposed top surface of the heat sinking seat 102, the light emitted from the LED chip 150 is able to radiate out of the packaging structure via the through hole. The through hole in the present embodiment has a circular aperture and the diameter of the aperture is larger as it is closer to the top. Please note that the geometric properties of the through hole here is only exemplary.

The LED chip 150 is fixedly adhered to the top surface of the heat sinking seat 102 as mentioned earlier. The positive and negative electrodes (not shown) of the LED chip 150 are connected to separate electrodes 104 of the base 100 respectively via the bonding wires 120. As such, the heat produced by the LED chip is dissipated through the heat sinking seat 102 (i.e., the heat dissipation channel) while the bonding wires 120 and the electrodes 104 jointly provide access to the electricity (i.e., the electricity channel). With this separation of the electricity and heat dissipation channels, superior heat dissipation efficiency is thereby achieved. The through hole of the reflection plate 160 is filled with the filler 130 made of a transparent material such as resin so as to seal and protect the LED chip 150 and the bonding wires 120. In the present embodiment, the filler 130 completely fills up the through hole of the reflection plate 110. In a second embodiment as shown in FIG. 2c, a transparent protection lens 170 (such as a dome-shaped lens commonly used for LEDs) is used to cover the LED chip 150 and the bonding wires 120.

FIGS. 2d˜2f are schematic sectional views showing the packaging structure according to a third, fourth, and fifth embodiments of the present invention respectively. For the third embodiment shown in FIG. 2d, a concaved reflection mirror 103 is formed on the top surface of the heat sinking seat 102 and beneath the LED chip 150. The reflection mirror 103 could be made of a metal or a metallic oxide having high thermal conductivity such as silver, aluminum, or aluminum oxide. The reflection mirror 103 could also be a coating of highly reflective material, regardless of its thermal conductivity. The purpose of having this reflection mirror 103 is to enhance the brightness of the LED chip 150 after it is packaged. The fourth embodiment shown in FIG. 2e is to demonstrate that the present invention could also be applied in producing white light from various colored LEDs and appropriate phosphors. In this embodiment, a blue-light LED chip 150 is buried inside a yellow phosphor 105 before they are sealed by the filler 130. The yellow phosphor 105 would produce yellow light as it is excited by the blue light from the LED chip 150, and the yellow light is mixed with the exciting blue light to produce two-wavelength white light. In another embodiment, an UV (ultra-violet) LED chip 150 is buried in red, green, and blue phosphors 105, and the red, green, and blue lights from the excitation of the red, green, and blue phosphors 105 by the UV light from the LED chip 150 are mixed to produce three-wavelength white light. A fifth embodiment shown in FIG. 2f is actually a combination of the third and fourth embodiments. A large number of research results about the reflection mirror 103 and the phosphors 105 have already been disclosed in the related arts, and their implementations are not limited to those exemplified in the afore-mentioned embodiments.

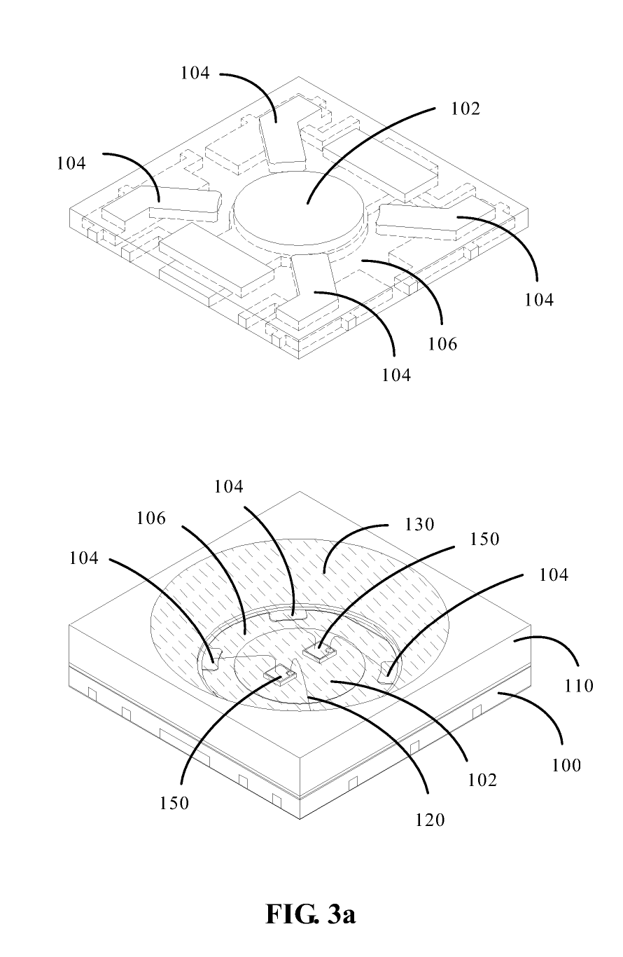

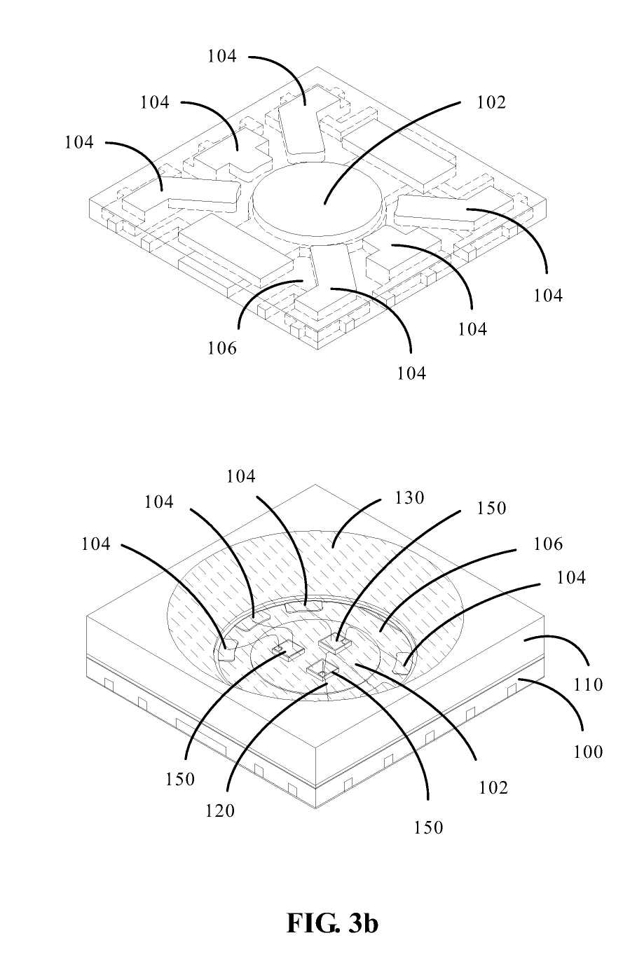

FIGS. 3a and 3b demonstrate how the present invention is applied in the packaging of two and three LED chips respectively, by showing their bases and packaging structures. As should be obvious from the illustrations, the present invention could be easily adapted to package an even larger number of the LED chips. The only difference between these multiple-chip packaging structures lies only in the formation of an appropriate number of electrodes 104 at appropriate positions in the base 100. The multiple-chip packaging structure is also very suitable for color-mixing various colored LEDs. Using the three-chip packaging structure shown in FIG. 3b as an example, the three LED chips 150 could be a red-light one, a green-light one, and blue-light one respectively. Then, by packaging them together in the illustrated packaging structure, the three colored lights would mix with each other to form white light. As a brief summary, the present invention could be applied in the packaging of various colored LED chips, various numbers of LED chips, and in the production of various mono-colored and full-colored lights.

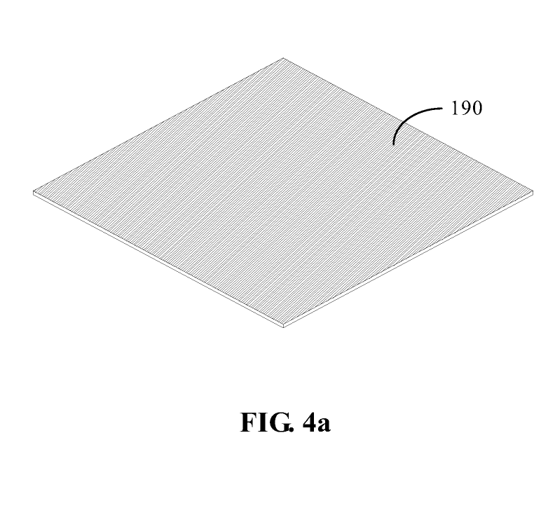

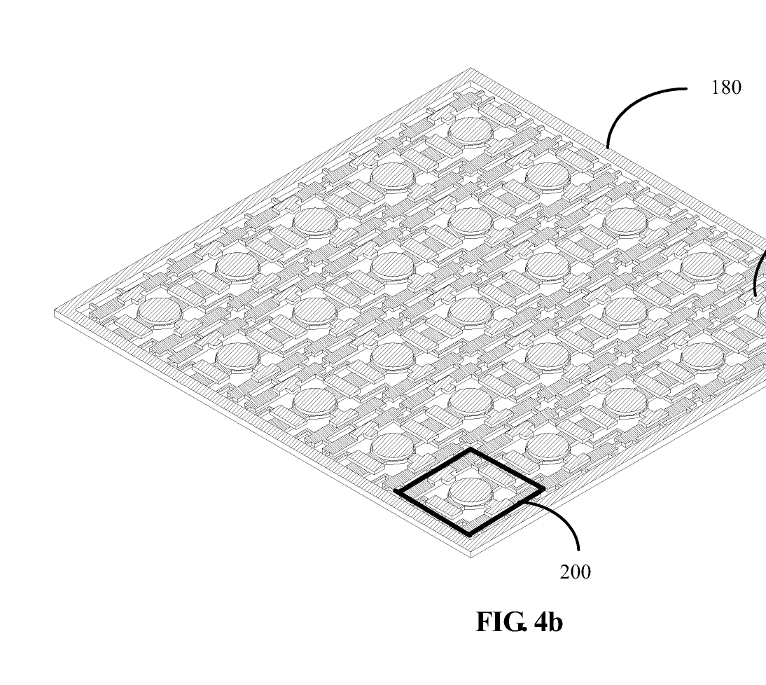

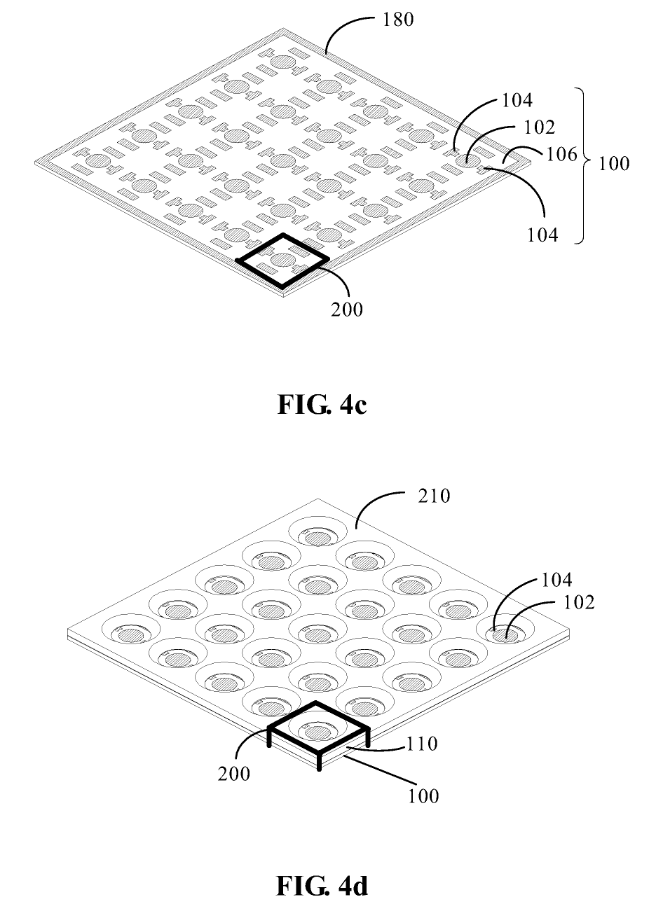

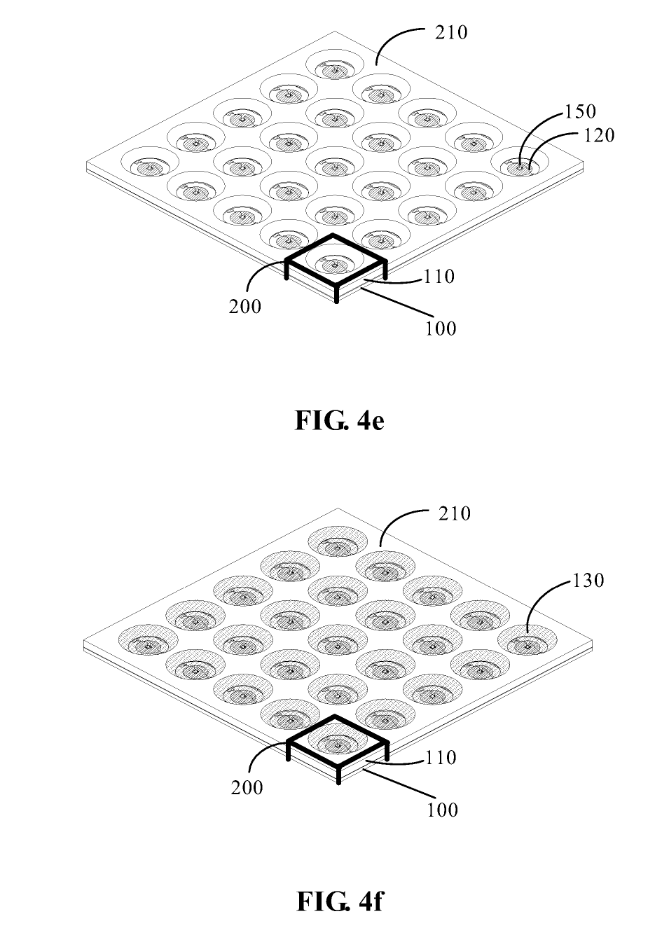

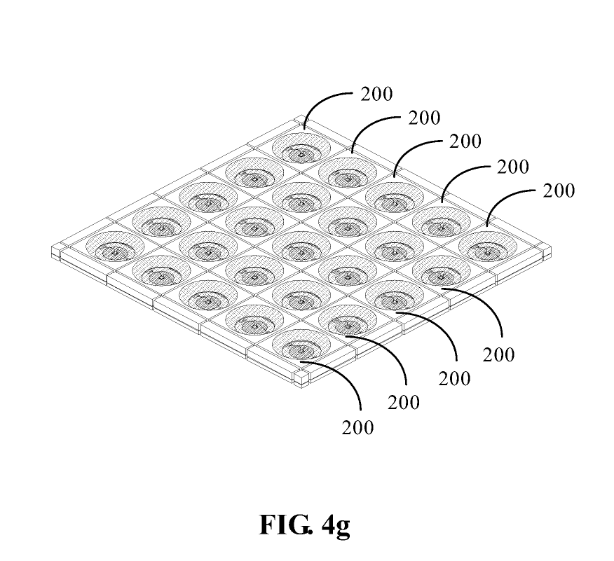

FIGS. 4a˜4g show the results of the processing steps of a fabrication method according to an embodiment of the present invention. Initially, a large metallic plate 190 having high electrical and thermal conductivities is provided, as shown in FIG. 4a. The metallic plate 190 is used for the subsequent formation of the bases 100 of multiple packaging units 200 simultaneously. The bases 100 of the packaging units 200 are arranged in an array, adjacent to each other or to the boarder 180 of the metallic plate 190. The bases 100 are formed mainly by appropriate means of etching and machinery to remove the part of the bases 100 for the subsequent filling of the insulator 106 and, after that, the heat sinking seats 102 and the electrodes 104 of the bases 100 are left behind, as shown in FIG. 4b. Then, the part of the bases 100 etched away is filled with the insulator 106 and the result is shown in FIG. 4c.

Depending on the complexity of the shapes of the heat sinking seat 102 and the electrodes 104, the foregoing etching and machinery process could be conducted to the two major surfaces of the metallic plate 190 simultaneously, producing the patterns of the heat sinking seats 102 and the electrodes 104 for all packaging units 200 in a single run. The filling of the insulator 106 is then performed subsequently. However, if the shapes of the heat sinking seat 102 and the electrodes 104 are rather complex, the etching and the filling of the insulator 106 could be conducted to a major surface of the metallic plate 190 in a first run, and then conducted to the other major surface in a second run. The formation of the bases 100 of all packaging units 200 is then completed.

Next, as shown in FIG. 4d, a previously prepared plate member 210 composed of multiple reflection plates 110 is adhered to the processed metallic plate 190 of FIG. 4c by an appropriate adhesive. Then, for each packaging unit 200, the fixation and wire bonding of the LED chip 150 is conducted, whose result is shown in FIG. 4e. The transparent filler 130 is then injected into the through holes of the reflection plates 110 to seal the packaging units 200, as shown in FIG. 4f. At last, as illustrated in FIG. 4g, the packaging units 200 are separated by cutting.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A fabrication method for producing a plurality of packaging units of high-power LED chips, comprising the steps of:
(1) forming said plurality of packaging units' bases on a metallic plate, each of said bases comprising a heat sinking seat, a plurality of electrodes having appropriate distances to said heat sinking seat, and an insulator, said insulator positioned among and adhering together said heat sinking seat and said plurality of electrodes so as to provide electrical insulation between said heat sinking seat and any one of said plurality of electrodes, and between any two of said plurality of electrodes;
(2) adhering a plate member to the top surface of said metallic plate processed by said step (1) with an appropriate adhesive, said plate member previously prepared to comprise a plurality of reflection plates corresponding to said bases, each of said plurality of reflection plates having a vertical through hole with an appropriate aperture at an appropriate location so as to expose a top surface of said heat sinking seat and at least a portion of a top surface of each of said plurality of electrodes of a corresponding base, the wall of said through hole having high reflectivity;
(3) fixing a LED chip on said exposed top surface of said heat sinking seat of each of said bases, and connecting the electrodes of said LED chip to said exposed top surfaces of said plurality of electrodes of said base by a plurality of bonding wires respectively;
(4) sealing said LED chip and said plurality of bonding wires of each of said plurality of packaging units by positioning one of a transparent filler and a transparent lens inside said through hole; and
(5) separating said plurality of packaging units by cutting.

2. The fabrication method for producing a plurality of packaging units of high-power LED chips according to claim 1, wherein said heat sinking seat of each of said bases is positioned such that said heat sinking seat has appropriate distances to the edges of said base and is exposed both from the top surface of said base, and from at least one of the bottom surface and a side surface of said base.

3. The fabrication method for producing a plurality of packaging units of high-power LED chips according to claim 1, wherein said plurality of electrodes of each of said bases are positioned around said heat sinking seat; and each of said plurality of electrodes is exposed both from the top surface of said base, and from at least one of the bottom surface and a side surface of said base.

4. The fabrication method for producing a plurality of packaging units of high-power LED chips according to claim 1, wherein said step (1) is conducted using etching and machinery on the two major surfaces of said metallic plate simultaneously to form said heat sinking seats and said plurality of electrodes of said bases; and then said insulator is filled to complete the formation of said bases.

5. The fabrication method for producing a plurality of packaging units of high-power LED chips according to claim 1, wherein said step (1) is conducted using etching and machinery first on a major surface of said metallic plate and said insulator is subsequently filled, and then using etching and machinery on the other major surface of said metallic plate and said insulator is subsequently filled, so as to complete the formation of said bases.

6. The fabrication method for producing a plurality of packaging units of high-power LED chips according to claim 1, wherein said reflection plate is made of a metallic material having high reflectivity.

7. The fabrication method for producing a plurality of packaging units of high-power LED chips according to claim 1, wherein said reflection plate is made of an insulating material and the wall of said through hole has a white coating of high reflectivity.

8. The fabrication method for producing a plurality of packaging units of high-power LED chips according to claim 1, wherein said reflection plate is made of an insulating material and the wall of said through hole is coated with a film made of highly reflective material.
